(19) United States
(12) Patent Application Publication
(10) Pub. No.: US 2022/0117076 A1
(43) Pub. Date: Apr. 14, 2022

(54) ELECTRONIC DEVICE

(71) Applicant: Nidec Chaun-Choung Technology Corporation, New Taipei City (TW)

(72) Inventors: Jason WANG, New Taipei City (TW); Vivian HSU, New Taipei City (TW); Lily WANG, New Taipei City (TW)

(21) Appl. No.: 17/499,382

(22) Filed: Oct. 12, 2021

(30) Foreign Application Priority Data
Oct. 12, 2020 (JP) 2020-172235

(51) Int. Cl. H05K 1/02

(52) U.S. Cl. CPC H05K 1/0209; H01L 23/427

(57) ABSTRACT

An electronic device includes a circuit board, an electronic component, and a cooling device mounted on the circuit board. The electronic component and the cooling device are mounted on the circuit board. The cooling device includes a thermal conductor and a cooler. The thermal conductor includes a working medium and a wick in an internal space of a metallic housing. The cooler includes an internal flow path through which a fluid can flow and is connected to an end portion of the thermal conductor.

### CROSS-REFERENCE TO RELATED APPLICATIONS

The present application claims priority under 35 U.S.C. § 119 to Japanese Patent Application No. 2020-172235, filed on Oct. 12, 2020, the entire contents of which are hereby incorporated herein by reference.

### 1. Field of the Invention

The present disclosure relates to an electronic device.

### 2. Background

Conventionally, a plurality of electronic components, such as a dual inline memory module (DIMM), are often mounted on a motherboard mounted on information devices such as a personal computer and a server device. The DIMM generates heat with information reading and writing processing. Conventionally, there are many cases where the DIMM is air-cooled by blowing air with a fan into a housing that houses the motherboard.

However, a reading speed and a writing speed of the DIMM become faster and faster in response to a demand for performance improvement of information devices and high-speed information processing, and the amount of heat generation accompanying this tends to increase. Therefore, there is a case where introduction of a cooling means, more efficient than air cooling by a fan, is desired for cooling of the electronic components such as the DIMM.

### SUMMARY

An example embodiment of an electronic device of the present disclosure includes a circuit board, an electronic component mounted on the circuit board, and a cooling device mounted on the circuit board. The cooling device includes a thermal conductor and a cooler. The thermal conductor includes a working medium and a wick accommodated in an internal space of a metallic housing. The cooler includes an internal flow path through which a fluid can flow and is connected to an end portion of the thermal conductor.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view illustrating a configuration example of an electronic device according to an example embodiment of the present disclosure.

FIG. 2 is a perspective view illustrating a configuration example of a cooling device according to an example embodiment of the present disclosure.

FIG. 3 is a cross-sectional view illustrating a configuration example of a thermal conductor according to an example embodiment of the present disclosure.

FIG. 4 is a cross-sectional view illustrating a first modification of a thermal conductor according to an example embodiment of the present disclosure.

FIG. 5 is a cross-sectional view illustrating a second modification of a thermal conductor according to an example embodiment of the present disclosure.

### DETAILED DESCRIPTION

Hereinafter, example embodiments will be described with reference to the drawings.

In the present specification, one of directions perpendicular to a normal direction of a circuit board 110 of an electronic device 100 is referred to as a “first direction D1”. One side in the first direction D1 is referred to as “one side in the first direction D1a”, and the other side is referred to as “the other side in the first direction D1b”. In each component, an end portion on the one side in the first direction D1a is referred to as “one end portion in the first direction”, and an end portion on the other side in the first direction D1b is referred to as “the other end portion in the first direction”. Among surfaces of each component, a surface facing the one side in the first direction D1a is sometimes referred to as “one end surface in the first direction”, and a surface facing the other side in the first direction is sometimes referred to as “the other end surface in the first direction”.

A direction parallel to the normal direction of the circuit board 110 is referred to as a “second direction D2”. One side in the second direction D2 is referred to as “one side in the second direction D2a”, and the other side is referred to as “the other side in the second direction D2b”. In each component, an end portion on the one side in the second direction D2a is referred to as “one end portion in the second direction”, and an end portion on the other side in the second direction D2b is referred to as “the other end portion in the second direction”. Among surfaces of each component, a surface facing the one side in the second direction D2a is sometimes referred to as “one end surface in the second direction”, and a surface facing the other side in the second direction is sometimes referred to as “the other end surface in the second direction”.

In addition, a direction perpendicular to both the first direction D1 and the second direction D2 is referred to as a “third direction D3”. One side in the third direction D3 is referred to as “one side in the third direction D3a”, and the other side is referred to as “the other side in the third direction D3b”. In each component, an end portion on the one side in the third direction D3a is referred to as “one end portion in the third direction”, and an end portion on the other side in the third direction D3b is referred to as “the other end portion in the third direction”. Among surfaces of each component, a surface facing the one side in the third direction D3a is sometimes referred to as “one end surface in the third direction”, and a surface facing the other side in the third direction is sometimes referred to as “the other end surface in the third direction”.

In a positional relationship between any one element and another element of an orientation, a line, and a surface, the term “parallel” includes not only a state in which these elements endlessly extend without intersecting at all but also a state in which these elements are substantially parallel. The terms “perpendicular” and “orthogonal” each include not only a state in which the both intersect at 90 degrees with each other but also a state in which the both are substantially perpendicular and a state in which the both are substantially orthogonal. In other words, the terms “parallel”, “perpendicular”, and “orthogonal” each include a state in which the positional relationship therebetween permits an angular deviation to a degree not departing from the gist of the present disclosure.

The “plate shape” includes not only a shape that spreads completely flat without unevenness and bending in a direction perpendicular to a predetermined normal direction but also a shape that spreads substantially flat. That is, the “plate shape” includes a shape that spreads flat in the direction perpendicular to the predetermined normal direction with an uneven and bent portion to a degree not departing from the gist of the present disclosure.

Note that these are names used merely for description, and are not intended to limit actual positional relationships, directions, shapes, names, and the like.

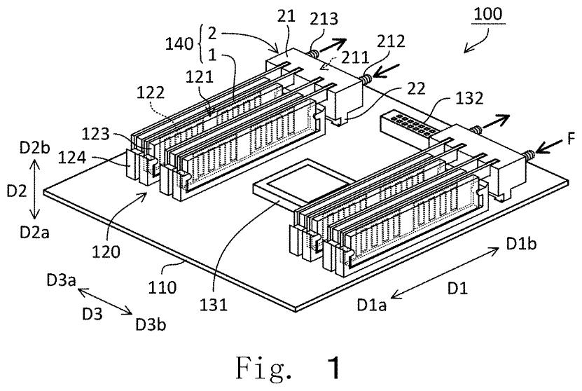

FIG. 1 is a perspective view illustrating a configuration example of the electronic device 100. As illustrated in FIG. 1, the electronic device 100 includes the circuit board 110, electronic component groups 120, and cooling devices 140 each of which includes a thermal conductor 1 and a cooler 2. In addition to the electronic component group 120 and the cooling device 140, the electronic device 100 includes other electronic components such as a CPU 141 and various connectors such as a power connector 142. These parts are mounted on the circuit board 110. However, drawings and descriptions of these parts are different from the gist of the present disclosure, and thus, will be omitted. In the present example embodiment, the electronic device 100 is a motherboard used for a personal computer and a server device. However, the application of the electronic device 100 is not limited to this example.

Each of the electronic component groups 120 includes a plurality of electronic components 121. In other words, the electronic device 100 includes the electronic components 121 mounted on the circuit board. The electronic component 121 has a plate shape in the present example embodiment, and spreads in the first direction D1 perpendicular to the normal direction of the circuit board 110 and the second direction D2 parallel to the normal direction of the circuit board 110. In each of the electronic component groups 120, the plurality of electronic components 121 are arranged in the third direction D3. Each of the electronic components 121 is mounted on the circuit board 110 via a socket 124 disposed on the circuit board 110.

The electronic component 121 includes a semiconductor circuit 122 and an electronic substrate 123 on which the semiconductor circuit 122 is mounted. In the present example embodiment, the semiconductor circuit 122 serving as a heat generation source can be efficiently cooled by the cooling device 140. The semiconductor circuit 122 is a memory circuit capable of storing information. That is, the electronic component 121 is a memory module such as a dual inline memory module (DIMM), and the memory circuit is mounted on the electronic substrate 123.

The electronic component 121 is disposed in the vicinity of the thermal conductor 1 of the cooling device 140 and is opposite to the thermal conductor 1 in the third direction D3. Specifically, in the third direction D3 perpendicular to the first direction D1 and the second direction D2, the electronic component 121 is opposite to a surface of the thermal conductor 1 facing the third direction D3. Therefore, the electronic component 121 can dissipate heat from the own surface spreading in the first direction D1 and second direction D2 to the surface of the thermal conductor 1 opposite to the electronic component 121. Therefore, the electronic component 121 can dissipate heat more efficiently by the thermal conductor 1.

Preferably, the semiconductor circuit 122 is disposed on a surface of the electronic substrate 123 facing the thermal conductor 1. At least some of the thermal conductors 1 are disposed between the electronic components 121 adjacent to each other in the third direction D3. Then, the thermal conductor 1 can cool the electronic components 121 disposed on both sides in the third direction D3.

In the present example embodiment, the cooling device 140 is mounted on the circuit board 110 in order to cool the electronic component 121. However, the present disclosure is not limited to this example, and the cooling device 140 may be used for cooling a part other than the electronic component 121. The cooling device 140 is advantageous for cooling a plate-shaped heat-generating body that spreads in the first direction D1 and the second direction D2, and particularly advantageous for cooling a plurality of heat-generating bodies arranged in the third direction D3.

In the present example embodiment, the plurality of electronic component groups 120 and the plurality of cooling devices 140 are provided. The cooling device 140 is attached to each of the electronic component groups 120. Then, the electronic component 121 can be cooled by the cooling device 140 attached to each of the electronic component groups 120 even if each of the electronic component groups 120 is disposed at a distant position since the cooling device 140 is attached for each of the electronic component groups 120. However, the present disclosure is not limited to this example, and each of the electronic component group 120 and the cooling device 140 may be singular. At this time, the cooling device 140 is mounted according to the number of the electronic component groups 120.

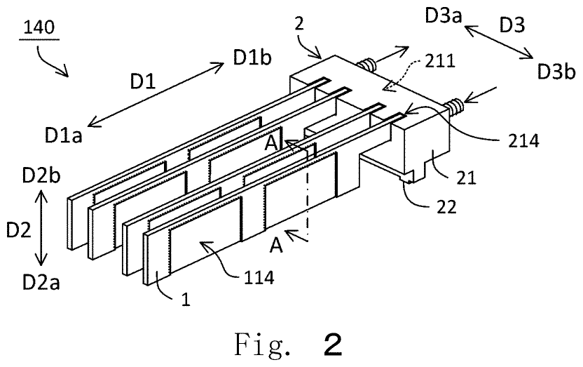

Next, a configuration of the cooling device 140 will be described with reference to FIGS. 1 and 2. FIG. 2 is a perspective view illustrating a configuration example of the cooling device 140. As described above, the electronic device 100 includes the cooling device 140, and the cooling device 140 is mounted on the circuit board 110.

As described above, the cooling device 140 includes the thermal conductor 1. The thermal conductor 1 is a member in which a working medium 13 and a wick structure 12 are accommodated in an internal space 113 of a metallic housing 11. The thermal conductor 1 has a plate shape in the present example embodiment, and extends from the cooler 2 in the one side in the first direction D1a and spreads in the second direction D2 perpendicular to the first direction D1. That is, the thermal conductor 1 spreads in the first direction D1 and the second direction D2. The thermal conductor 1 is disposed in the vicinity of the electronic component 121 and is opposite to the electronic component 121.

As described above, the cooling device 140 includes the cooler 2. The cooler 2 has an internal flow path 211 through which a fluid F can flow as will be described later. The cooler 2 is connected to an end portion of the thermal conductor 1 so as to be capable of transferring heat. Specifically, the other end portion in the first direction of the thermal conductor 1 is connected to the cooler 2 so as to be capable of conducting heat. Note that the fluid F is a refrigerant. As the fluid F, for example, antifreeze, such as ethylene glycol and propylene glycol, or a liquid, such as pure water, can be employed.

The cooling device 140 can cool the electronic component 121. For example, the electronic component 121 can dissipate heat to the thermal conductor 1 of the cooling device 140. The heat transferred to the thermal conductor 1 is dissipated to the cooler 2 at the end portion of the thermal conductor 1. Since the fluid F flows through the internal flow path 211 of the cooler 2, the cooler 2 can efficiently release the heat transferred from the thermal conductor 1 to the fluid F. Therefore, the electronic device 100 can further improve a heat transfer property of the thermal conductor 1, and thus, the cooling efficiency of the electronic component 121 can be further enhanced.

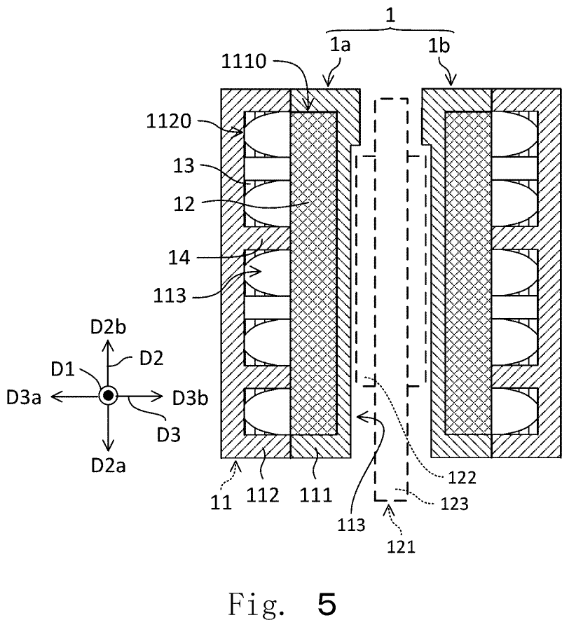

In each of the cooling devices 140, the plurality of thermal conductors 1 are arranged in the third direction D3. Then, the plurality of electronic components 121 can be cooled. For example, when the plurality of electronic components 121 are disposed in the third direction D3, the thermal conductor 1 can be disposed in the vicinity of each of the electronic components 121 in the third direction D3, and thus, each of the electronic components 121 can be cooled. In addition, the cooling efficiency of the electronic component 121 can be further improved. For example, the thermal conductor 1 can be disposed on both the sides in the third direction D3 of the electronic component 121, and thus, the electronic component 121 can be cooled from both the sides in the third direction D3 (see FIG. 5 to be described later). Note that four thermal conductors 1 are disposed in each of the cooling devices 140 in the present example embodiment. However, the present disclosure is not limited to this example, and the number of the thermal conductors 1 of each of the cooling devices 140 may be one, or two or more except for four.

The cooler 2 is a member configured to cool the thermal conductor 1. The cooler 2 includes a jacket portion 21 in which the internal flow path 211 is disposed. The jacket portion 21 includes the above-described internal flow path 211, an inlet 212, and an outlet 213. The internal flow path 211 is a flow path through which the fluid F flows, and is disposed inside the jacket portion 21. The internal flow path 211 is connected to the inlet 212 and the outlet 213. The inlet 212 and the outlet 213 are connected to a pump device (not illustrated) that circulates the fluid F, a radiator device (not illustrated) that cools the fluid F, and the like. As the pump device is driven, the fluid F circulates through the internal flow path 211, the radiator device, and the pump device.

The fluid F flows into the internal flow path 211 from the inlet 212. While the fluid F flows inside the internal flow path 211, heat transferred from the thermal conductor 1 to the jacket portion 21 is released to the fluid F. The fluid F to which the heat has been transferred flows out to the outside of the internal flow path 211 from the outlet 213 and is cooled by the radiator device. The cooled fluid F returns to the internal flow path 211 and flows again from the inlet 212. The cooler 2 can cool the thermal conductor 1 through the above heat transfer cycle.

The jacket portion 21 further includes a recess 214 for accommodating an end portion of the thermal conductor 1. That is, the cooler 2 has the recess 214. A part of the thermal conductor 1 is disposed in the recess 214. Specifically, the recess 214 is disposed at one end portion in the first direction of the jacket portion 21 and is recessed toward the other side in the first direction D1b. The recess 214 accommodates the other end portion in the first direction of the thermal conductor 1, so that the thermal conductor 1 is fixed and supported by the jacket portion 21. Note that the other end portion in the first direction of the thermal conductor 1 may be fixed by being press-fitted into the recess 214. Alternatively, the fixing may be performed by soldering using silver solder or the like, welding, and the like. Then, for example, a side surface of the end portion of the thermal conductor 1 is in contact with an inner side surface of the recess 214, so that a heat conduction area between the thermal conductor 1 and the cooler 2 can be further widened. Therefore, the cooling efficiency of the thermal conductor 1 by the cooler 2 can be enhanced.

A material of the jacket portion 21 is copper in the present example embodiment, but is not limited to this example. For example, any metal, such as copper, iron, aluminum, zinc, silver, gold, magnesium, manganese, and titanium, or an alloy (brass, stainless steel, duralumin, or the like) containing these metals can be used as the material of the jacket portion 21.

The cooler 2 further includes a leg portion 22. The leg portion 22 protrudes from the jacket portion 21 toward the circuit board 110 and is fixed to the circuit board 110. As the leg portion 22 is fixed to the circuit board 110, the cooling device 140 can be fixed to the circuit board 110. In the present example embodiment, the leg portion 22 is inserted into a through-hole (whose reference sign is omitted) disposed in the circuit board 110 and fixed using an adhesive. However, a method for fixing the leg portion 22 is not limited to this example. The leg portion 22 may be fixed by so-called snap-fit. Alternatively, the leg portion 22 may be directly bonded without being inserted into the through-hole. Alternatively, the leg portion 22 may be screwed to the circuit board 110 or may be fixed using a fixing jig.

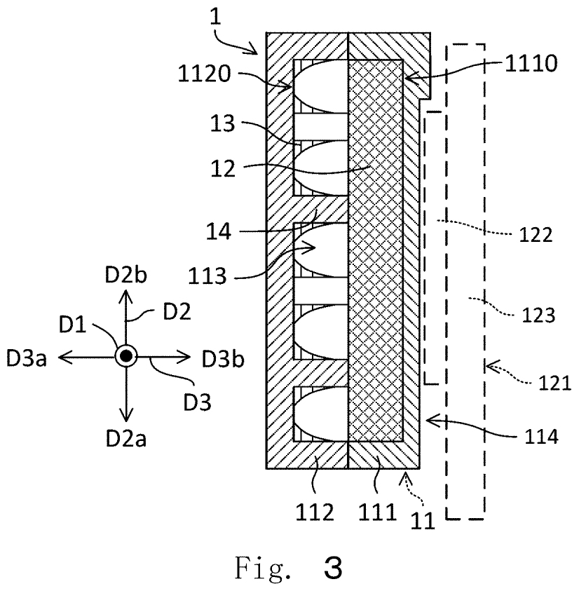

Next, a configuration of the thermal conductor 1 will be described with reference to FIGS. 1 to 3. FIG. 3 is a cross-sectional view illustrating a configuration example of the thermal conductor. FIG. 3 illustrates a cross-sectional structure of the thermal conductor 1 taken along an alternate long and short dash line A-A in FIG. 2.

The thermal conductor 1 is a so-called vapor chamber, and cools the electronic component 121 in the present example embodiment. The thermal conductor 1 includes the metallic housing 11, the wick structure 12, the working medium 13, and a column portion 14.

The other end portion in the first direction of the housing 11 is connected to the cooler 2 so as to be thermally conductive (see FIG. 2). In addition, one end portion in the second direction of the other end portion in the first direction of the housing 11 is disposed on the other side in the second direction D2b with respect to one end portion in the second direction of a portion on the one side in the first direction D1a of the housing 11. Then, when the thermal conductor 1 is disposed such that the one side in the second direction D2a is directed vertically downward, the working medium 13 liquefied at the other end portion in the first direction of the internal space 113 of the housing 11 easily flows into a portion on the one side in the first direction D1a of the internal space 113 due to a height difference in the vertical direction. Therefore, the heat transfer efficiency of the thermal conductor 1 can be further improved. In a case where a cooling target uses a fixing jig such as the socket 124, the thermal conductor 1 can be disposed in the vicinity of the electronic component 121 without contact of the jig by providing the above-described difference in height.

The housing 11 includes a first metal plate 111 and a second metal plate 112. In the third direction D3, the first metal plate 111 is disposed opposite to the second metal plate 112. The first metal plate 111 has a recess 1110. The recess 1110 is disposed at one end portion in the third direction of the first metal plate 111 and is recessed to the other side in the third direction D3b. The second metal plate 112 has a recess 1120 overlapping with the recess 1110 when viewed from the third direction D3. The recess 1120 is disposed at the other end portion in the third direction of the second metal plate 112 and is recessed to the one side in the third direction D3a.

Further, the housing 11 has the internal space 113 for accommodating the wick structure 12 and the working medium 13. The internal space 113 is disposed between the first metal plate 111 and the second metal plate 112. Specifically, outer peripheral edges of the first metal plate 111 and the second metal plate 112 are joined to each other, whereby the sealed internal space 113 is formed inside the housing 11. The recess 1110 and the recess 1120 form the internal space 113 in the present example embodiment. Note that the present disclosure is not limited to this example, and either the recess 1110 or the recess 1120 may be omitted. That is, the internal space 113 is formed of at least one of the recess 1110 of the first metal plate 111 and the recess 1120 of the second metal plate 112.

In the present example embodiment, the first metal plate 111 and the second metal plate 112 are joined by hot pressing. However, the present disclosure is not limited to this example, and the both may be joined by soldering or welding using, for example, silver solder or the like. Further, the both may be directly joined, or may be joined via a metal plating layer such as copper.

A material of the first metal plate 111 and the second metal plate 112 is copper in the present example embodiment. However, materials of the first metal plate 111 and the second metal plate 112 are not limited to the above example. For example, any metal, such as copper, iron, aluminum, zinc, silver, gold, magnesium, manganese, and titanium, or an alloy (brass, stainless steel, duralumin, or the like) containing these metals can be used as the materials of the first metal plate 111 and the second metal plate 112.

Next, the housing 11 further includes a housing recess 114. In other words, the thermal conductor 1 has the housing recess 114. The housing recess 114 is disposed on a surface of the housing 11 facing the electronic component 121. Specifically, the housing recess 114 is disposed on a surface of the housing 11 facing the semiconductor circuit 122. The housing recess 114 is recessed in a direction away from the electronic component 121 and is opposite to the semiconductor circuit 122. When viewed from the third direction D3, the housing recess 114 overlaps with the entire semiconductor circuit 122. When the thermal conductor 1 is disposed opposite to a surface of the electronic component 121 on which the semiconductor circuit 122 is mounted, the housing recess 114 can accommodate a part of each of the semiconductor circuits 122. This part is a portion of the semiconductor circuit 122 on the housing recess 114 side in the third direction. Then, the thermal conductor 1 can be disposed at a position closer to the electronic component 121 to such an extent that the housing 11 does not come into contact with the semiconductor circuit 122. Since an interval between the thermal conductor 1 and the electronic component 121 can be further shortened, the cooling efficiency of the electronic component 121 by the thermal conductor 1 can be further improved.

The housing recess 114 extends to one end portion in the second direction of the housing 11, that is, is open to the one end portion in the second direction of the housing 11. Then, it is easy to dispose the thermal conductor 1. That is, when the thermal conductor 1 is moved from the other side in the second direction D2b to the one side in the second direction D2a to be disposed opposite to the electronic component 121, the housing 11 is less likely to come into contact with the semiconductor circuit 122. Therefore, it is easy to attach the thermal conductor 1 to the electronic component 121. In other words, the cooling device 140 can be easily attached to the electronic component group 120.

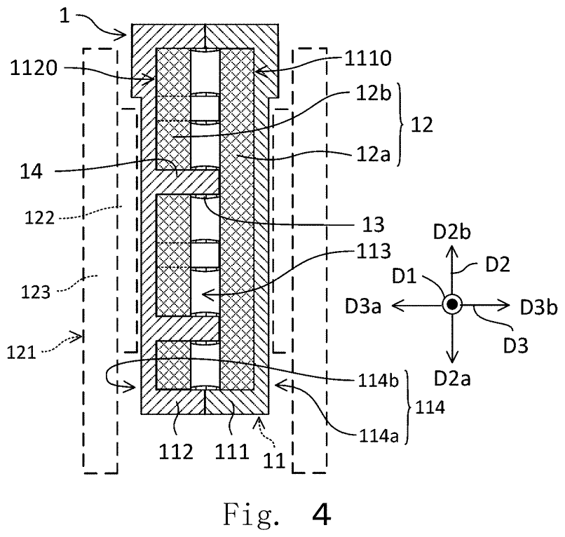

In the present example embodiment, the semiconductor circuit 122 is disposed on only one surface among surface of the electronic substrate 123 facing the third direction D3 in the electronic component 121. Further, in the respective electronic component groups 120, the semiconductor circuits 122 are disposed only on the surfaces of the electronic substrates 123 facing the same side in the third direction D3 in all the electronic components 121. Therefore, the housing recess 114 is disposed only on one surface among the surfaces of the housing 11 facing the third direction D3 in the thermal conductor 1 of FIG. 3. However, the present disclosure is not limited to this example, and the housing recess 114 may be disposed on both end surfaces in the third direction D3 of the housing 11 (for example, see FIG. 4 described later). Then, even if the electronic components 121 are disposed on both the sides in the third direction D3 of the thermal conductor 1 and the semiconductor circuits 122 are disposed on the surfaces of the electronic substrates 123 on the side facing the thermal conductor 1 in the third direction D3 in both the electronic components 121, the thermal conductors 1 can be disposed at positions closer to the electronic components 121, respectively, to such an extent that the housings 11 do not come into contact with the semiconductor circuits 122. The same applies to a case where the semiconductor circuits 122 are not disposed only on the surfaces of the electronic substrates 123 facing the same side in the third direction D3 in the respective electronic components 121. Therefore, the thermal conductor 1 can efficiently cool both the electronic components 121 disposed on both the sides in the third direction D3.

Next, the wick structure 12 has a capillary structure. The liquefied working medium 13 can permeate the wick structure 12. In the present example embodiment, the wick structure 12 is a porous metallic sintered body such as a sintered body of metal powder such as copper. However, the wick structure 12 is not limited to this example. The wick structure 12 may have a mesh shape. Alternatively, at least a part of the wick structure 12 may be a part of the housing 11, and may include, for example, a plurality of grooves disposed on a surface of the first metal plate 111 facing the second metal plate 112. A material of the wick structure 12 is copper in the present example embodiment. However, the present disclosure is not limited to this example, and another metal or alloys, carbon fibers, and ceramics may be adopted.

The wick structure 12 is disposed on the inner surface on the first metal plate 111 side in the internal space 113, and is disposed on a bottom surface of the recess 1110 of the first metal plate 111 in the present example embodiment. In other words, the wick structure 12 is disposed on the inner surface of the internal space 113 on the electronic component 121 side. That is, the wick structure 12 is disposed on the side to which heat is transferred from the electronic component 121, which is a heat source, in the internal space 113. Then, the heat can be efficiently transferred from the electronic component 121 to the wick structure 12 into which the liquid working medium 13 permeates, and thus, the cooling efficiency of the electronic component 121 can be improved.

In addition, the wick structure 12 is disposed on the inner surface of the internal space 113 facing the third direction D3. Then, the thermal conductor 1 can be disposed in parallel with the electronic component 121, and thus, the electronic component 121 can dissipate heat more evenly to the surface of the thermal conductor 1 opposite to the electronic component 121. That is, a deviation of a heat transfer coefficient from the electronic component 121 can be reduced or prevented on the surface of the thermal conductor 1 opposite to the electronic component 121. Therefore, the electronic component 121 can more efficiently dissipate heat to the thermal conductor 1.

Next, the working medium 13 is vaporized by the heat transferred from the heat source and evaporates in the internal space 113. In the present example embodiment, the heat source is the electronic component 121. Here, preferably, the sealed internal space 113 is depressurized and its internal pressure is lower than atmospheric pressure. Then, the working medium 13 is more easily vaporized. The working medium 13 is cooled and liquefied at a portion of the housing 11 away from the heat source. The liquefied working medium 13 penetrates into the wick structure 12 and is refluxed to the vicinity of a portion with which the heat source is in contact. Through the above cycle in which the working medium 13 is vaporized and liquefied, the thermal conductor 1 can transfer the heat, which has been transferred from the heat source, to the portion of the housing 11 away from the heat source and dissipate the heat.

The working medium 13 is pure water in the present example embodiment, but may be a medium other than water. For example, the working medium 13 may be any of alcohol compounds such as methanol and ethanol, alternatives for chlorofluorocarbons such as hydrofluorocarbon, hydrocarbon compounds such as propane and isobutane, fluorinated hydrocarbon compounds such as difluoromethane, ethylene glycol, and the like. The working medium 13 can be employed according to a use environment of the thermal conductor 1.

Next, the column portion 14 protrudes from the second metal plate 112 toward the first metal plate 111 and is disposed inside the internal space 113 in the present example embodiment. More specifically, the column portion 14 protrudes from a bottom surface of the recess 1120 toward the first metal plate 111. In the present example embodiment, a plurality of the column portions 14 are disposed integrally with the second metal plate 112. That is, the column portion 14 and the second metal plate 112 are respectively different parts of the single member. However, the present disclosure is not limited to this example, and the column portion 14 may be a single member or a member different from the second metal plate 112.

A distal end of the column portion 14 is in contact with the wick structure 12 in the present example embodiment. Alternatively, the distal end may be in contact with the first metal plate 111 through a through-hole provided in the wick structure 12. As a result, the column portion 14 supports the first metal plate 111 and the second metal plate 112 between the both. Therefore, even when a force acts on an outer side surface of the first metal plate 111 and/or the second metal plate 112, the housing 11 is less likely to be deformed, and it is possible to suppress narrowing of the internal space 113 due to the deformation of the housing 11. Note that the present disclosure is not limited to the example of the present example embodiment, and at least a part of the column portion 14 may protrude from the first metal plate 111.

Next, modifications of the thermal conductor 1 will be described. In each modification, a configuration different from that of the above example embodiment and other modifications will be described. Moreover, configurations similar to those in the above example embodiments and other modifications will be denoted by the same reference signs, and detailed descriptions thereof will be omitted.

First, a first modification of the thermal conductor 1 will be described with reference to FIG. 4. FIG. 4 is a cross-sectional view illustrating the first modification of the thermal conductor 1. Note that FIG. 4 corresponds to the cross-sectional structure of the thermal conductor 1 taken along the alternate long and short dash line A-A in FIG. 2.

In the first modification, the wick structures 12 are disposed on inner surfaces of the internal space 113 on both sides in the third direction D3. For example, as illustrated in FIG. 4, the wick structures 12 include a first wick structure 12a and a second wick structure 12b. The first wick structure 12a is disposed on the inner surface of the internal space 113 facing the one side in the third direction D3a. The second wick structure 12b is disposed on the inner surface of the internal space 113 facing the other side in the third direction D3b. Then, the working medium 13 which is the liquid can be vaporized on both the sides in the third direction D3 in the internal space 113 of the thermal conductor 1. Therefore, the thermal conductor 1 can efficiently dissipate the heat, which has been transferred to both side surfaces of the housing 11 in the third direction D3, to the cooler 2. Therefore, the thermal conductor 1 can cool, for example, the electronic components 121 disposed on both the sides in the third direction D3.

In the first modification, preferably, the housing recesses 114 are disposed on both the end surfaces in the third direction D3 of the housing 11. For example, in FIG. 4, the housing recesses 114 include a first housing recess 114a and a second housing recess 114b . The first housing recess 114a is disposed on the other end surface in the third direction of the housing 11 and is recessed to the one side in the third direction D3a. The second housing recess 114b is disposed on the one end surface in the third direction of the housing 11 and is recessed to the other side in the third direction D3b. Both the first housing recess 114a and the second housing recess 114b extend to the one end portion in the second direction of the housing 11, that is, are open to the one end portion in the second direction of the housing 11. Then, even if the electronic components 121 are disposed on both the sides in the third direction D3 of the thermal conductor 1 and the semiconductor circuits 122 are disposed on the surfaces of the electronic substrates 123 on the side facing the thermal conductor 1 in the third direction D3 in both the electronic components 121, the thermal conductors 1 can be disposed at positions closer to the electronic components 121, respectively, to such an extent that the housings 11 do not come into contact with the semiconductor circuits 122. Therefore, the thermal conductor 1 can efficiently cool both the electronic components 121 disposed on both the sides in the third direction D3. However, this example does not exclude a configuration in which the housing recess 114 is disposed only on the one end surface in the third direction D3 of the housing 11 and does not exclude a configuration in which the housing recess 114 is not disposed on both the end surfaces in the third direction D3 of the housing 11 in the first modification.

Next, a second modification of the thermal conductor 1 will be described with reference to FIG. 5. FIG. 5 is a cross-sectional view illustrating the second modification of the thermal conductor 1. Note that FIG. 5 corresponds to the cross-sectional structure of the thermal conductor 1 taken along the alternate long and short dash line A-A in FIG. 2.

In at least one cooling device 140, the plurality of thermal conductors 1 include a first thermal conductor 1a and a second thermal conductor 1b. The second thermal conductors 1b are adjacent to each other in the third direction D3 with the electronic component 121 interposed therebetween. The first thermal conductor 1a is disposed on the one side in the third direction with respect to the electronic component 121. The wick structure 12 of the first thermal conductor 1a is disposed on the inner surface of the internal space 113 facing the one side in the third direction D3a. The second thermal conductor 1b is disposed on the other side in the third direction D3b with respect to the electronic component 121. The wick structure 12 of the second thermal conductor 1b is disposed on the inner surface of the internal space 113 facing the other side in the third direction D3b. Thus, both the sides in the third direction D3 of the electronic component 121 disposed between the first thermal conductor 1a and the second thermal conductor 1b can be cooled. Therefore, a cooling effect of the electronic component 121 can be improved. This effect is particularly advantageous, for example, in a case where the semiconductor circuits 122 are mounted on both the end surfaces in the third direction D3 of the electronic substrate 123 in the electronic component 121 disposed between the first thermal conductor 1a and the second thermal conductor 1b as illustrated in FIG. 5.

In the second modification, preferably, the housing recess 114 of the first thermal conductor 1a and the housing recess 114 of the second thermal conductor 1b are opposite to each other in the third direction D3, that is, are disposed on the surfaces of the housings 11 facing the electronic components 121 in the third direction D3. For example, in FIG. 5, the housing recess 114 of the first thermal conductor 1a is disposed on the other end surface in the third direction of the housing 11. The housing recess 114 of the second thermal conductor 1b is disposed on the one end surface in the third direction of the housing 11. Then, in the electronic component 121 disposed between the first thermal conductor 1a and the second thermal conductor 1b, the first thermal conductor 1a and the second thermal conductor 1b can be disposed at positions closer to the electronic component 121 to such an extent that the respective housing 11 do not come into contact with the semiconductor circuits 122, respectively, even if the semiconductor circuits 122 are disposed on both the sides in the third direction D3 of the electronic substrate 123. The electronic component 121 can dissipate the heat generated in the semiconductor circuit 122 disposed on the one end surface in the third direction of the electronic substrate 123 to the first thermal conductor la, and dissipate the heat generated in the semiconductor circuit 122 disposed on the other end surface in the third direction of the electronic substrate 123 to the second thermal conductor 1b. Therefore, the cooling effect of the electronic component 121 can be enhanced to more reliably cool the electronic component. However, this example does not exclude a configuration in which the housing recess 114 is not disposed in at least one of the first thermal conductor 1a and the second thermal conductor 1b in the second modification.

The present disclosure is advantageous for a device that cools an electronic component mounted on a circuit board.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An electronic device comprising:
a circuit board;
an electronic component mounted on the circuit board; and
a cooling device mounted on the circuit board; wherein the cooling device includes:
a thermal conductor in which a working medium and a wick are accommodated in an internal space of a metallic housing; and
a cooler which includes an internal flow path which allows flow of a fluid and is connected to an end portion of the thermal conductor.

2. The electronic device according to claim 1, wherein
the electronic component includes a semiconductor circuit and an electronic substrate on which the semiconductor circuit is mounted.

3. The electronic device according to claim 2, wherein
the semiconductor circuit is a memory circuit capable of storing information.

4. The electronic device according to claim 3, wherein
the semiconductor circuit is on a surface of the electronic substrate opposing the thermal conductor; and
the wick is on an inner surface of the internal space on a side of the electronic component.

5. The electronic device according to claim 4, wherein
the thermal conductor further includes a housing recess on a surface of the housing opposing the electronic component; and
the housing recess is recessed in a direction away from the electronic component and is opposite to the semiconductor circuit.

6. The electronic device according to claim 1, wherein
the electronic component spreads in a first direction perpendicular to a normal direction of the circuit board and a second direction parallel to the normal direction of the circuit board; and
in a third direction perpendicular to the first direction and the second direction, the electronic component is opposite to a surface of the thermal conductor opposing the third direction.

7. The electronic device according to claim 6, wherein
the thermal conductor spreads in the first direction and the second direction; and
the wick is on an inner surface of the internal space opposing the third direction.

8. The electronic device according to claim 7, further comprising:
an electronic component group in which a plurality of the electronic components are arranged in the third direction; wherein
the thermal conductor is between the electronic components adjacent to each other in the third direction.

9. The electronic device according to claim 8, wherein
a plurality of the electronic component groups and a plurality of the cooling devices are provided; and
the cooling devices are attached to the electronic component groups, respectively.

10. The electronic device according to claim 6, wherein the wick includes:
a first wick on an inner surface of the internal space opposing one side in the third direction; and
a second wick on an inner surface of the internal space opposing another side in the third direction.

11. The electronic device according to claim 6, wherein
a plurality of the thermal conductors are arranged in the third direction.

12. The electronic device according to claim 6, wherein
a plurality of the thermal conductors include a first thermal conductor and a second thermal conductor adjacent to the first thermal conductor with the electronic component interposed between the first thermal conductor and the second thermal conductor in the third direction;
the first thermal conductor is on one side in the third direction with respect to the electronic component;
the wick of the first thermal conductor is on an inner surface of the internal space opposing the one side in the third direction;
the second thermal conductor is on another side in the third direction with respect to the electronic component; and
the wick of the second thermal conductor is on an inner surface of the internal space opposing the another side in the third direction.

13. The electronic device according to claim 1, wherein the cooler includes:
a jacket portion in which the internal flow path is located; and
a leg portion which protrudes from the jacket portion toward the circuit board and is fixed to the circuit board.
